(19) United States
(12) Patent Application Publication
(10) Pub. No.: US 2015/0014037 A1
(43) Pub. Date: Jan. 15, 2015

(54) MULTILAYER CERAMIC CAPACITOR AND BOARD FOR MOUNTING THE SAME

(71) Applicant: SAMSUNG ELECTRO-MECHANICS CO., LTD., Suwon (KR)

(72) Inventors: Young Ghyu AHN, Suwon (KR); Doo Young KIM, Suwon (KR); Min Cheol PARK, Suwon (KR); Byoung Hwa LEE, Suwon (KR); Sang Soo PARK, Suwon (KR)

(73) Assignee: SAMSUNG ELECTRO-MECHANICS CO., LTD., Suwon (KR)

(21) Appl. No.: 14/067,808

(22) Filed: Oct. 30, 2013

(30) Foreign Application Priority Data
Jul. 11, 2013 (KR) 10-2013-0081736

(51) Int. Cl. H01G 4/30; H05K 1/18

(52) U.S. Cl. CPC H01G 4/30; H05K 1/181
USPC 174/260; 361/301.4

(57) ABSTRACT

There is provided a multilayer ceramic capacitor including a ceramic body including a plurality of dielectric layers stacked in a width direction, a plurality of first and second internal electrodes, first and second lead parts having at least one space part and extended from the first internal electrode to be exposed through the bottom surface of the ceramic body and be spaced apart from each other in a length direction, a third lead part positioned between the first and second lead parts and extended from the second internal electrode, first and second external electrodes formed on the bottom surface of the ceramic body and electrically connected to the first and second lead parts, respectively, and a third external electrode formed between the first and second external electrodes and electrically connected to the third lead part.

### CROSS-REFERENCE TO RELATED APPLICATION

This application claims the benefit of Korean Patent Application No. 10-2013-0081736 filed on Jul. 11, 2013, with the Korean Intellectual Property Office, the disclosure of which is incorporated herein by reference.

### BACKGROUND OF THE INVENTION

1. Field of the Invention

The present invention relates to a multilayer ceramic capacitor and a board for mounting the same.

2. Description of the Related Art

An example of electronic components using a ceramic material includes a capacitor, an inductor, a piezoelectric element, a varistor, a thermistor, and the like.

Among the ceramic electronic components, a multilayer ceramic capacitor (MLCC) has advantages in that it has a small size and a high capacitance and is easily mounted, and is usefully employed as a decoupling capacitor disposed in a high frequency circuit such as a power supply circuit of a large scale integrated circuit (LSI), or the like.

Here, stability of the power supply circuit depends on an equivalent series inductance (ESL) of the multilayer ceramic capacitor and is relatively high, particularly in a low ESL.

Therefore, in order to stabilize the power supply circuit, the multilayer ceramic capacitor should have a low ESL. This demand has further increased in accordance with the trend toward an increase in a frequency and a current of an electronic apparatus.

In addition, the multilayer ceramic capacitor is also used as an electromagnetic interference (EMI) filter in addition to the decoupling capacitor. In this case, the ESL needs to be relatively low in order to remove high frequency noise and improve attenuation characteristics.

In order to decrease the ESL, a three-terminal type capacitor in which internal electrodes are mounted to be perpendicular to a surface of a board and dielectric layers formed of a ceramic material and internal electrode formed of a metal are alternately stacked at corner portions and both end surfaces of a ceramic body has been partially disclosed.

However, in the three-terminal type multilayer ceramic capacitor, since coupling force between the dielectric layer and the internal electrode is relatively weak, there was a problem in that delamination is generated at the corner portions and both end surfaces of the ceramic body.

The following Related Art Document discloses a three-terminal type multilayer ceramic capacitor, but does not disclose a unit for solving the problem that the delamination is generated at the corner portions and both end surfaces of the ceramic body.

### RELATED ART DOCUMENT

### Korean Patent Laid-Open Publication No. 10-2008-0073193

### SUMMARY OF THE INVENTION

An aspect of the present invention provides a multilayer ceramic capacitor capable of decreasing an equivalent series inductance (ESL) and preventing occurrence of delamination in corner portions and both end surfaces of a ceramic body.

According to an aspect of the present invention, there is provided a multilayer ceramic capacitor including: a ceramic body including a plurality of dielectric layers stacked in a width direction; a plurality of first and second internal electrodes alternately disposed, having the dielectric layers interposed therebetween; first and second lead parts having at least one space part and extended from the first internal electrode so as to be exposed through the bottom surface of the ceramic body and be spaced apart from each other in a length direction; a third lead part positioned between the first and second lead parts and extended from the second internal electrode so as to be exposed through the bottom surface of the ceramic body; first and second external electrodes formed on the bottom surface of the ceramic body to be spaced apart from each other and electrically connected to the first and second lead parts, respectively; and a third external electrode formed on the bottom surface of the ceramic body between the first and second external electrodes and electrically connected to the third lead part.

When a total area of the space part included in the first or second lead part is S2 and an area corresponding to the sum of an area of the first or second lead part and S2 is S1, S2/S1 may range from 10.0% to 90.1%.

When a minimum width of the first or second lead part exposed to the bottom surface of the ceramic body is A and a width of the first or second external electrode formed on the bottom surface of the ceramic body is B, 36 μm≦A≦100.1 μm and A≦B.

The first and second lead parts may be extended from the first internal electrode so as to be exposed through the top surface of the ceramic body.

The multilayer ceramic capacitor may further include: a fourth lead part positioned between the first and second lead parts and extended from the second internal electrode so as to be exposed through the top surface of the ceramic body; and a fourth external electrode formed on the top surface of the ceramic body between the first and second external electrodes and electrically connected to the fourth lead part.

The first and second external electrodes may be extended to both end surfaces of the ceramic body.

The first to third external electrodes may be extended to at least portions of both side surfaces of the ceramic body.

The space part provided in the first or second lead part may be exposed through at least one surface of the dielectric layer.

The space part provided in the first or second lead part may be formed in a position corresponding to a corner portion of the dielectric layer.

The space part provided in the first or second lead part may be exposed through one end surface of the dielectric layer.

The space part provided in the first or second lead part may be formed in a position corresponding to a corner portion of the dielectric layer so as to be exposed through one end surface of the dielectric layer.

The third lead part may have a space part exposed through a lower surface of the dielectric layer.

The fourth lead part may have a space part exposed through an upper surface of the dielectric layer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view schematically showing a multilayer ceramic capacitor according to an embodiment of the present invention;

FIG. 2 is a transparent perspective view showing a structure of internal electrodes of the multilayer ceramic capacitor according to the embodiment of the present invention;

FIGS. 3A and 3B are plan views showing first and second internal electrodes of the multilayer ceramic capacitor according to the embodiment of the present invention;

FIG. 4 is a plan view showing a total area S2 of a space part of the multilayer ceramic capacitor according to the embodiment of the present invention and an area S1 corresponding to the sum of a first or second lead part and the space part;

FIG. 5 is a plan view showing another example of a first internal electrode of the multilayer ceramic capacitor according to the embodiment of the present invention;

FIG. 6 is a plan view showing another example of a first internal electrode of the multilayer ceramic capacitor according to the embodiment of the present invention;

FIG. 7 is a plan view showing another example of a second internal electrode of the multilayer ceramic capacitor according to the embodiment of the present invention;

FIG. 8 is a perspective view showing another example of an external electrode of the multilayer ceramic capacitor according to the embodiment of the present invention;

FIGS. 9A and 9B are plan views showing another example of first and second internal electrodes of the multilayer ceramic capacitor of FIG. 8;

FIG. 10 is a perspective view showing another example of an external electrode of the multilayer ceramic capacitor according to the embodiment of the present invention;

FIGS. 11A and 11B are plan views showing another example of first and second internal electrodes of the multilayer ceramic capacitor of FIG. 10; and

FIG. 12 is a perspective view schematically showing a form in which the multilayer ceramic capacitor according to the embodiment of the present invention is mounted on a printed circuit board.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

Hereinafter, the multilayer ceramic electronic component according to the embodiment of the present invention will be described. Particularly, a multilayer ceramic capacitor will be described. However, the present invention is not limited thereto.

### Multilayer Ceramic Capacitor

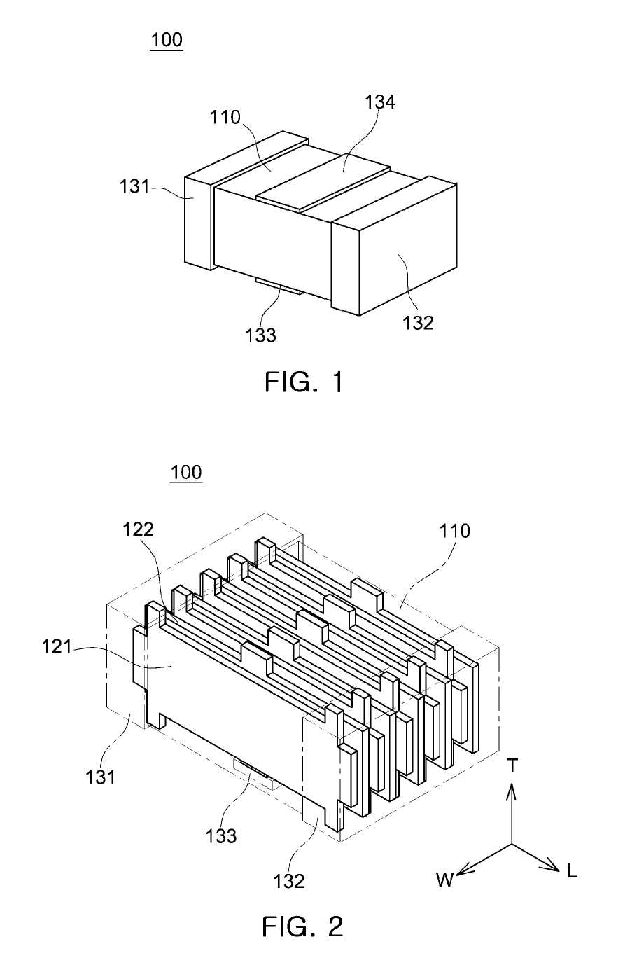

FIG. 1 is a perspective view schematically showing a multilayer ceramic capacitor according to an embodiment of the present invention; and FIG. 2 is a transparent perspective view showing a structure of internal electrodes of the multilayer ceramic capacitor according to the embodiment of the present invention.

Referring to FIGS. 1 and 2, the multilayer ceramic capacitor 100 according to the embodiment of the present invention may include a ceramic body 110, a plurality of first and second internal electrodes 121 and 122, first to third lead parts 123, 124 and 125, and firth to third external electrodes 131 to 133 formed on the bottom surface of the ceramic body 110.

The ceramic body 110 may be formed by stacking a plurality of dielectric layers 111 in a width direction and then firing the plurality of dielectric layers 111. Dielectric layers 111 adjacent to each other may be integrated with each other so as not to confirm a boundary therebetween without using a scanning electron microscope (SEM).

A shape of the ceramic body 110 is not particularly limited. For example, the ceramic body 110 may have a hexahedral shape.

A direction of a hexahedron of the ceramic body 110 will be defined in order to clearly describe the embodiments of the present invention. L, W and T shown in FIG. 2 refer to a length direction, a width direction, and a thickness direction, respectively.

Further, in the present embodiment, for convenience of explanation, end surfaces of the ceramic body 110 opposing each other in the thickness direction will be defined as first and second main surfaces, end surfaces connecting the first main surface to the second main surface and opposing each other in the length direction will be defined as first and second end surfaces, and surfaces opposing each other in the width direction will be defined as first and second side surfaces.

The dielectric layer 111 may include a high-k ceramic material, for example, a barium titanate (BaTiO₃) based ceramic powder, or the like. However, the present invention is not limited thereto as long as a sufficient capacitance may be obtained.

In addition, the dielectric layer 111 may further include various kinds of ceramic additives, organic solvents, plasticizers, binders, dispersants, and the like, such as a transition metal oxide or carbide, rare earth elements, magnesium (Mg), aluminum (Al), or the like, in addition to the ceramic powder, as necessary.

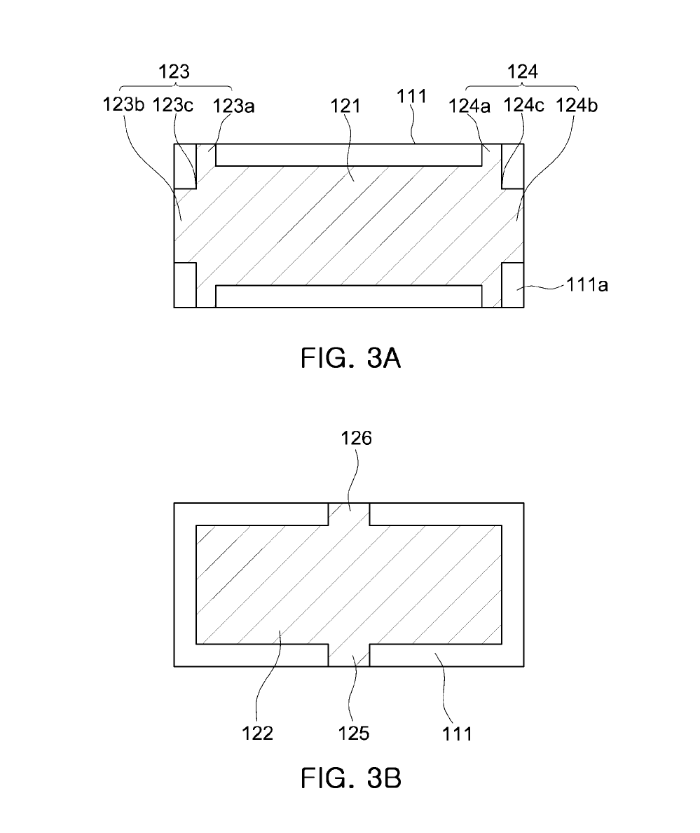

FIGS. 3A and 3B are plan views showing first and second internal electrodes of the multilayer ceramic capacitor according to the embodiment of the present invention.

Referring to FIGS. 3A and 3B, the first and second internal electrodes 121 and 122, having different polarities, may be alternately disposed to face each other, having a ceramic sheet therebetween, and be overlapped with each other in a stacked direction to contribute to a capacitance of the capacitor, wherein the ceramic sheet forms the dielectric layer 111.

The first and second internal electrodes 121 and 122 may be electrically insulated from each other by the dielectric layer 111 disposed therebetween.

In addition, the first and second internal electrodes 121 and 122 may be formed of a conductive material, for example, any one of silver (Ag), palladium (Pd), platinum (Pt), nickel (Ni) and copper (Cu) or an alloy thereof. However, the present invention is not limited thereto.

The first and second lead parts 123 and 124, extended from the first internal electrode 121 so as to be exposed through at least one surface of the ceramic body 110, may have at least one or more space parts 123c and 124c, and may include a pair of first exposed parts 123a and 124a exposed from the first internal electrode 121 through the second main surface of the ceramic body 110 and second exposed parts 123b and 124b extended so as to be exposed through the first and second end surfaces of the ceramic body 110 opposing each other, respectively.

Here, the space parts 123c and 124c, corresponding to parts at which ceramic materials having high coupling force contact each other, are secured at corner portions and the first and second end surfaces of the ceramic body 110, whereby delamination generated at the corner portions and the first and second end surfaces of the ceramic body 110 may be significantly decreased.

Here, the space parts 123c and 124c may have a form in which they are exposed through at least one surface of the dielectric layer. In the present embodiment, the space parts 123c and 124c may be formed in positions corresponding to the corner portions of the dielectric layer 111 between the first exposed parts 123a and 124a and the second exposed parts 123b and 124b. However, the present invention is not limited thereto.

The third lead part 125 may be positioned between the first and second lead parts 123 and 124 and be extended from the second internal electrode 122 so as to be exposed through the second main surface of the ceramic body 110.

The first and second external electrodes 131 and 132, having the same polarity, may be formed on the second main surface of the ceramic body 110. In the present embodiment, the first and second external electrodes 131 and 132 may be extended to the first and second end surfaces of the ceramic body 110 and contact the first and second lead parts 123 and 124 exposed through the second main surface and the first and second end surfaces of the ceramic body 110, respectively, to thereby be electrically connected to the first and second lead parts 123 and 124.

That is, since the first and second lead parts 123 and 124 contact the first and second external electrodes 131 and 132 corresponding thereto, respectively, over the first and second end surfaces and the second main surface of the ceramic body 110 at a relatively wide area, an effect of decreasing an equivalent series inductance (ESL) may be obtained.

Here, the first and second external electrodes 131 and 132 may be extended to portions of the first and second side surfaces of the ceramic body 110 or be extended to the first main surface of the ceramic body 110 and may be formed in a form in which they completely cover both end portions of the ceramic body 110 as necessary.

The third external electrode 133, having a polarity different from those of the first and second external electrodes 131 and 132, may be formed on the second main surface of the ceramic body 110 between the first and second external electrodes 131 and 132 and may contact the third lead part 125 exposed through the second main surface of the ceramic body 110 to thereby be electrically connected to the third lead part 125.

Here, the first to third external electrodes 131 to 133 may be formed of a conductive metal, for example, silver (Ag), nickel (Ni), copper (Cu), or the like. The first to third external electrodes 131 to 133 may be formed by applying and firing a conductive paste prepared by adding glass frits to conductive metal powder. However, the present invention is not limited thereto.

In addition, a plating layer (not shown) may be formed on the first to third external electrodes 131 to 133 as necessary. The plating layer is to increase adhesion strength between the multilayer ceramic capacitor 100 and the printed circuit board when the multilayer ceramic capacitor 100 is mounted on the printed circuit board using a solder.

The plating layer may include, for example, a nickel (Ni) plating layer formed on the first to third external electrodes 131 to 133 and a tin (Si) plating layer formed on the nickel plating layer. However, the present invention is not limited thereto.

Meanwhile, the first and second lead parts 123 and 124 may be extended so that the first exposed parts 123a and 124a are further exposed from the first internal electrode 121 through the first main surface of the ceramic body 110.

In addition, a fourth lead part 126 may be further formed to be extended so as to be exposed from the second internal electrode 122 through the first main surface of the ceramic body 110.

The fourth lead part 126 may be positioned between the first and second lead parts 123 and 124 so as to be spaced apart from the first and second lead parts 123 and 124.

Here, a fourth external electrode 134 may be formed on the first main surface of the ceramic body 110 between the first and second external electrodes 131 and 132. The fourth external electrode 134 may contact a portion of the fourth lead part 126 exposed through the first main surface of the ceramic body 110 to thereby be electrically connected to the exposed portion.

As described above, in the case in which the first and second lead parts 123 and 124 and the fourth lead part 126 are exposed to the first main surface of the ceramic body 110 to form internal and external structures of the multilayer ceramic capacitor 100 as a vertically symmetrical structure, directivity of the capacitor may be removed.

Therefore, since any surface of the first and second main surfaces may be provided as a mounting surface at the time of surface-mounting the capacitor, a direction of the mounting surface at the time of mounting the multilayer ceramic capacitor 100 on the printed circuit board needs not to be considered.

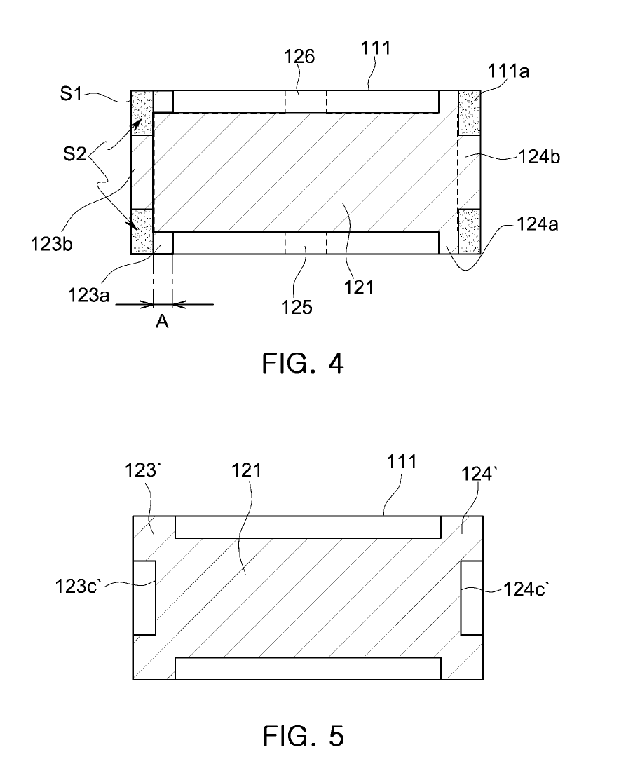

FIG. 4 is a plan view showing an area of a space part of the multilayer ceramic capacitor according to the embodiment of the present invention and an area corresponding to the sum of a lead part and the space part, and the following Table 1 illustrates whether or not delamination is generated depending on a value of S2/S1 and a value A to be described below and an ESL value.

TABLE 1

| | | | | | Delamination | |
|---|---|---|---|---|---|---|
| | S1 | S2 | | A | generation rate | ESL |
| Sample | (μm²) | (μm²) | S2/S1 | (μm) | (%) | (pH) |
| 1 | 36024 | 0 | 0.0% | 125.4 | 4.5 | 52.2 |
| 2 | 36023 | 1915 | 5.3% | 125.2 | 1.0 | 52.3 |
| 3 | 36028 | 2144 | 6.0% | 100.4 | 0.5 | 52.8 |
| 4 | 36018 | 3592 | 10.0% | 100.1 | 0.0 | 52.9 |
| 5 | 36032 | 3587 | 10.0% | 99.8 | 0.0 | 52.9 |
| 6 | 36034 | 3589 | 10.0% | 85.5 | 0.0 | 53.1 |
| 7 | 36011 | 10048 | 27.9% | 85.0 | 0.0 | 53.2 |
| 8 | 36025 | 15844 | 44.0% | 85.1 | 0.0 | 53.2 |
| 9 | 36018 | 23250 | 64.6% | 85.4 | 0.0 | 53.4 |
| 10 | 36030 | 28827 | 80.0% | 85.2 | 0.0 | 53.7 |
| 11 | 36009 | 28833 | 80.1% | 52.4 | 0.0 | 54.0 |
| 12 | 36025 | 28848 | 80.1% | 48.2 | 0.0 | 54.3 |
| 13 | 36019 | 32467 | 90.1% | 36.0 | 0.0 | 54.9 |
| 14 | 36022 | 34562 | 95.9% | 28.3 | 0.0 | 60.2 |

Referring to FIG. 4 and Table 1, when a total area of the space part 123c or 124c included in the first or second lead part 123 or 124 is S2 and an area corresponding to the sum of an area of the first or second lead part 123 or 124 and S2 is S1, S2/S1 may satisfy the range of 10.0% to 90.1% as in Samples 4 to 13 of Table 1.

When the value of S2/S1 is less than 10.0%, delamination may be generated as in Samples 1 to 3 of Table 1, and when the value of S2/S1 exceeds 90.1%, an ESL value exceeds 55 as in Sample 14 of Table 1, such that it may be difficult to implement a relatively low ESL.

When a minimum width of the first or second lead part 123 or 124, that is, a width of the first exposed part 123a or 124a in the present embodiment, is A, A may satisfy the range of 36.0 μm≦A≦100.1 μm as in Samples 4 to 13 of Table 1.

When the value A is less than 36.0 μm, it may be difficult to implement the relatively low ESL as in Sample 14 of Table 1, and when the value A exceeds 100.1 μm, the delamination may be generated as in Samples 1 to 3 of Table 1.

In addition, when a width of a band part of the first or second external electrode 131 or 132, that is, a width of a portion formed on the second surface, which is a mounting surface of the ceramic body 110, is B, the value A may be equal to or less than the value B.

Here, when the value A is larger than the value B, the internal electrode is externally exposed, such that reliability may be significantly decreased due to permeation of a plating solution, external moisture, and the like, in a plating process.

### Modified Example

FIG. 5 is a plan view showing another example of a first internal electrode of the multilayer ceramic capacitor according to the embodiment of the present invention.

Here, since a structure in which the ceramic body 110, the first and second internal electrodes 121 and 122, the first to third external electrodes 131 to 133, and the like, are formed is the same as that of the above-mentioned example, a detailed description thereof will be omitted so as to avoid an overlapped description, and first and second lead parts 123′ and 124′ having a structure different from that of the above-mentioned example will be described in detail.

Referring to FIG. 5, the first and second lead parts 123′ and 124′ may be formed in positions corresponding to corner portions of the dielectric layer 111 and be formed in positions corresponding to the upper and lower corner portions vertically opposing each other, respectively, as necessary.

Therefore, a space part 123c′ or 124c′ may be formed between the first or second lead parts 123′ or 124′ formed at upper and lower corner portions of the first internal electrode 121 so as to be exposed through the first and second end surfaces of the dielectric layer 111.

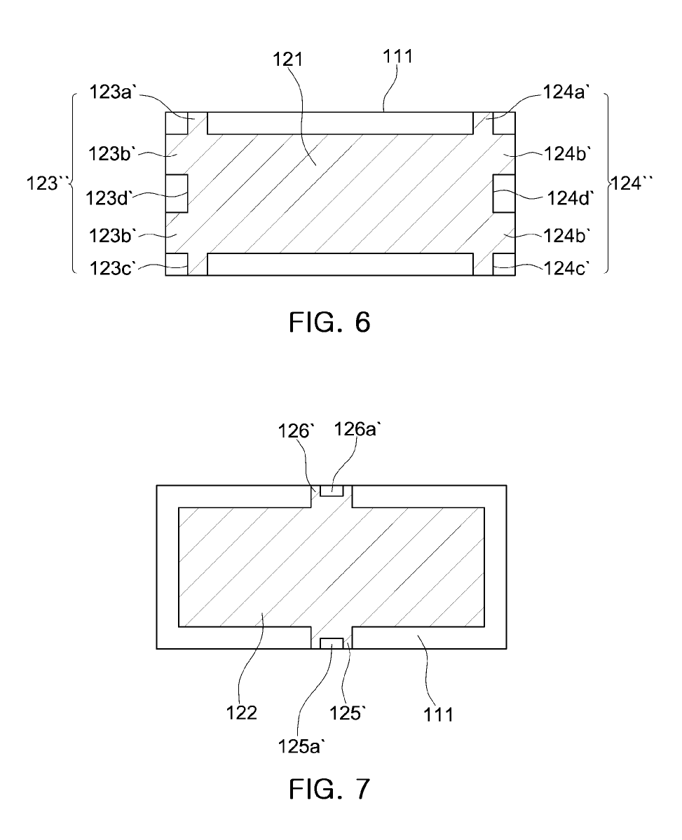

FIG. 6 is a plan view showing another example of a first internal electrode of the multilayer ceramic capacitor according to the embodiment of the present invention.

Here, since a structure in which the ceramic body 110, the first and second internal electrodes 121 and 122, the first to third external electrodes 131 to 133, and the like, are formed is the same as that of the above-mentioned example, a detailed description thereof will be omitted so as to avoid an overlapped description, and first and second lead parts 123″ and 124″ having a structure different from that of the above-mentioned example will be described in detail.

Referring to FIG. 6, the first and second lead parts 123″ and 124″ may include first exposed parts 123a′ and 124a′ exposed through the first and second main surfaces of the dielectric layer 111 and a plurality of second exposed parts 123b′ and 124b′ exposed through the first and second end surfaces of the dielectric layer 111.

Here, first space parts 123c′ and 124c′ may be provided between the first exposed parts 123a′ and 124a′ and the second exposed parts 123b′ and 124b′, that is, in positions corresponding to upper and lower corner portions of the dielectric layer 111, respectively, and second space parts 123d′ and 124d′ may be provided between the respective second exposed parts 123b′ and 124b′ so as to be exposed through the first and second end surfaces of the dielectric layer 111, respectively.

FIG. 7 is a plan view showing another example of a second internal electrode of the multilayer ceramic capacitor according to the embodiment of the present invention.

Here, since a structure in which the ceramic body 110, the first and second internal electrodes 121 and 122, the first to third external electrodes 131 to 133, and the like, are formed is the same as that of the above-mentioned example, a detailed description thereof will be omitted so as to avoid an overlapped description, and third and fourth lead parts 125′ and 126′ having a structure different from that of the above-mentioned example will be described in detail.

Referring to FIG. 7, the third and fourth lead parts 125′ and 126′ may have at least one space part 125a′ and 126a′, respectively, so as to be exposed through the first and second main surfaces of the dielectric layer 111, respectively.

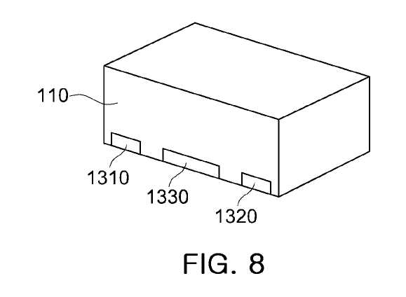

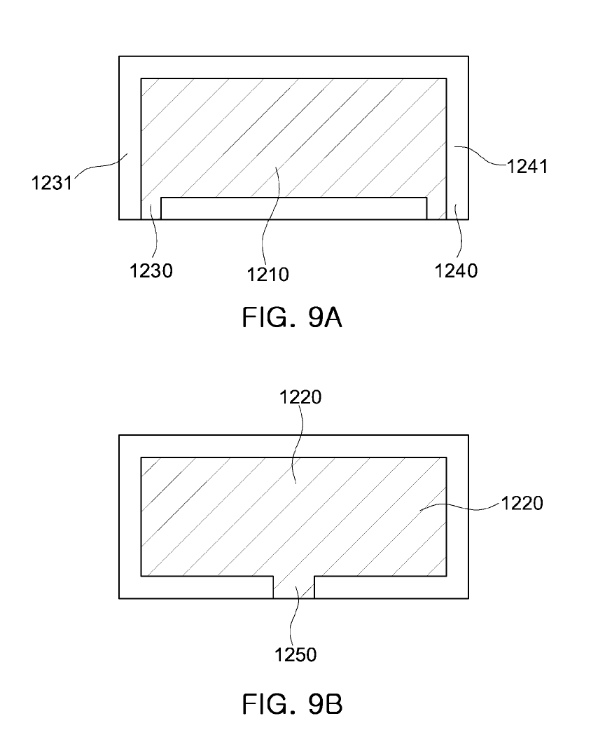

FIG. 8 is a perspective view showing another example of an external electrode of the multilayer ceramic capacitor according to the embodiment of the present invention; and FIGS. 9A and 9B are plan views showing another example of first and second internal electrodes of the multilayer ceramic capacitor of FIG. 8.

Here, since a structure of the ceramic body 110 is the same as that of the above-mentioned example, a detailed description thereof will be omitted so as to avoid an overlapped description, and first to third external electrodes 1310, 1320, and 1330 and first and second internal electrodes 1210 and 1220 having a structure different from that of the above-mentioned example will be described in detail.

Referring to FIGS. 8 through 9B, the first to third external electrodes 1310, 1320, and 1330 may only be formed on the bottom surface of the ceramic body 110 and be extended to portions of the first and second side surfaces of the ceramic body 110 as necessary.

In addition, the first internal electrode 1210 may include first and second lead parts 1230 and 1240 exposed through the bottom surface of the ceramic body 110 to thereby be electrically connected to the first and second external electrodes 1310 and 1320, respectively.

Here, the first internal electrode 1210 may include space parts 1231 and 1241 formed on both end portions thereof in the length direction.

The second internal electrode 1220 may include a third lead part 1250 positioned between the first and second lead parts 1230 and 1240 and exposed through the bottom surface of the ceramic body 110 to thereby be electrically connected to the third external electrode 1330.

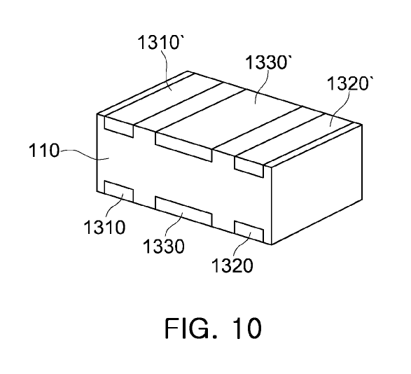

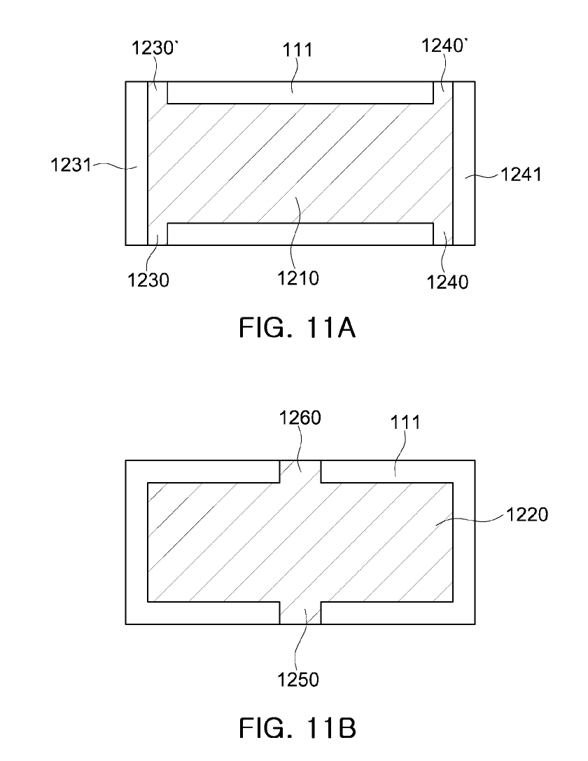

FIG. 10 is a perspective view showing another example of an external electrode of the multilayer ceramic capacitor according to the embodiment of the present invention; and FIGS. 11A and 11B are plan views showing another example of first and second internal electrodes of the multilayer ceramic capacitor of FIG. 10.

Here, since a structure of the ceramic body 110 is the same as that of the above-mentioned example, a detailed description thereof will be omitted so as to avoid an overlapped description, and first to third external electrodes 1310, 1320, and 1330 and first and second internal electrodes 1210 and 1220 having a structure different from that of the above-mentioned example will be described in detail.

Referring to FIGS. 10 through 11B, the first to third external electrodes 1310, 1310′ 1320, 1320′, 1330, and 1330′ may be formed on the top and bottom surfaces of the ceramic body 110 in a symmetrical form in which they oppose each other and be extended to portions of the first and second side surfaces of the ceramic body 110, respectively, as necessary.

In addition, the first internal electrode 1210 may include first and second lead parts 1230 and 1240 exposed through the bottom surface of the ceramic body 110 to thereby be electrically connected to the first and second external electrodes 1310 and 1320, respectively.

In addition, the first internal electrode 1210 may include first and second lead parts 1230′ and 1240′ exposed through the top surface of the ceramic body 110 to thereby be electrically connected to the first and second external electrodes 1310′ and 1320′ formed on the top surface of the ceramic body 110, respectively.

Here, the first internal electrode 1210 may include space parts 1231 and 1241 formed on both end portions thereof in the length direction.

The second internal electrode 1220 may include a third lead part 1250 exposed through the bottom surface of the ceramic body 110 to thereby be electrically connected to the third external electrode 1330 and a fourth lead part 1260 exposed through the top surface of the ceramic body 110 to thereby be electrically connected to the third external electrode 1330′, between the first and second lead parts 1230, 1230′, 1240 and 1240′, respectively.

### Board for Mounting Multilayer Ceramic Capacitor

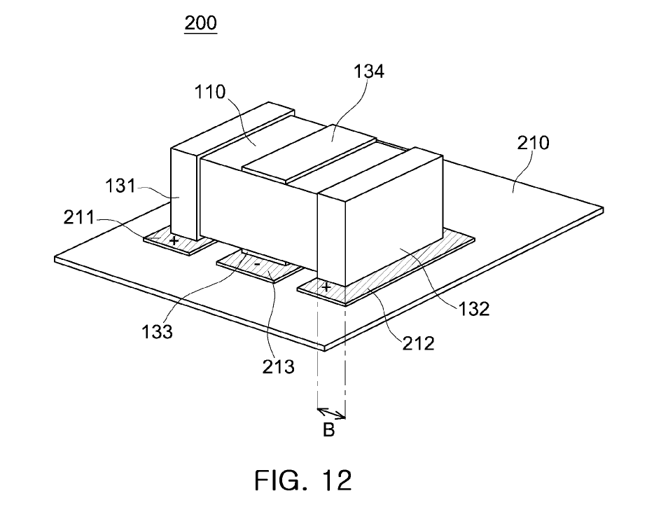

FIG. 12 is a perspective view schematically showing a form in which the multilayer ceramic capacitor according to the embodiment of the present invention is mounted on a printed circuit board.

Referring to FIG. 12, a board 200 for mounting the multilayer ceramic capacitor 100 according to the present embodiment may include a printed circuit board 210 having the multilayer ceramic capacitor 100 mounted thereon and first to third electrode pads 211 to 213 on an upper surface of the printed circuit board 210 so as to be spaced apart from each other.

Here, the multilayer ceramic capacitor 100 may be electrically connected to the printed circuit board 210 by a solder (not shown) in a state in which the second main surface of the ceramic body 110 in the thickness direction, which is amounting surface, may be disposed at a lower side and the first to third external electrodes 131 to 133 are positioned on the first to third electrode pads 211 to 213 so as to contact the first to third electrode pads 211 to 213, respectively.

In the multilayer ceramic capacitor 100 according to the present embodiment, since the first and second internal electrodes are disposed perpendicularly to the printed circuit board 210, a current may directly flow from the first to third electrode pads 211 to 213 of the printed circuit board 210 to the first and second internal electrodes 121 and 122 through thicknesses of the first to third external electrodes 131 to 133 without a separate current path.

Therefore, an ESL may be decreased as compared with a capacitor including internal electrodes disposed horizontally to the printed circuit board. The ESL may be further decreased as the number of stacked layers is increased.

As an application example, in the case in which the multilayer ceramic capacitor 100 is used as a three-terminal EMI filter, the first and second external electrodes 131 and 132 may be connected to input and output terminals of a signal line, respectively, and the third external electrode 133 may be connected to a ground terminal to remove high frequency noise of the signal line.

In this case, the first and second electrode pads 211 and 212, positive (+) poles, may correspond to the input/output terminals, respectively, and the third electrode pad 213, a negative (−) pole, may correspond to the ground terminal.

As another application example, in the case in which the multilayer ceramic capacitor 100 is used as a decoupling capacitor, the first and second external electrodes 131 and 132 may be connected to a power supply line and the third external electrode 133 may be connected to a ground line to stabilize a power supply circuit.

In this case, the first and second electrode pads 211 and 212 may correspond to the power supply line and the third electrode pad 213 may correspond to the ground line.

As set forth above, according to the embodiment of the present invention, since the ESL of the multilayer ceramic capacitor may be decreased, in the case in which the multilayer ceramic capacitor is used as a decoupling capacitor, an EMI filter, and the like, a voltage variation of a power supply circuit may be more effectively suppressed and high frequency attenuation characteristics and a high frequency noise removing effect may be improved.

In addition, parts at which the dielectric layers formed of ceramic materials having high coupling force contact each other may be secured at corner portions and both end surfaces of the ceramic body, whereby generation of a delamination phenomenon at the corner portions and both end surfaces of the ceramic body may be prevented.

While the present invention has been shown and described in connection with the embodiments, it will be apparent to those skilled in the art that modifications and variations can be made without departing from the spirit and scope of the invention as defined by the appended claims.

1. A multilayer ceramic capacitor comprising:
a ceramic body including a plurality of dielectric layers stacked in a width direction;
a plurality of first and second internal electrodes alternately disposed, having the dielectric layers interposed therebetween;
first and second lead parts having at least one space part and extended from the first internal electrode so as to be exposed through the bottom surface of the ceramic body and be spaced apart from each other in a length direction;
a third lead part positioned between the first and second lead parts and extended from the second internal electrode so as to be exposed through the bottom surface of the ceramic body;
first and second external electrodes formed on the bottom surface of the ceramic body to be spaced apart from each other and electrically connected to the first and second lead parts, respectively; and
a third external electrode formed on the bottom surface of the ceramic body between the first and second external electrodes and electrically connected to the third lead part.

2. The multilayer ceramic capacitor of claim 1, wherein when a total area of the space part included in the first or second lead part is S2 and an area corresponding to the sum of an area of the first or second lead part and S2 is S1, S2/S1 ranges from 10.0% to 90.1%.

3. The multilayer ceramic capacitor of claim 1, wherein when a minimum width of the first or second lead part exposed to the bottom surface of the ceramic body is A and a width of the first or second external electrode formed on the bottom surface of the ceramic body is B, 36 μm≦A≦100.1 μm and A≦B.

4. The multilayer ceramic capacitor of claim 1, wherein the first and second lead parts are extended from the first internal electrode so as to be exposed through the top surface of the ceramic body.

5. The multilayer ceramic capacitor of claim 1, further comprising:
a fourth lead part positioned between the first and second lead parts and extended from the second internal electrode so as to be exposed through the top surface of the ceramic body; and
a fourth external electrode formed on the top surface of the ceramic body between the first and second external electrodes and electrically connected to the fourth lead part.

6. The multilayer ceramic capacitor of claim 1, wherein the first and second external electrodes are extended to both end surfaces of the ceramic body.

7. The multilayer ceramic capacitor of claim 1, wherein the first to third external electrodes are extended to at least portions of both side surfaces of the ceramic body.

8. The multilayer ceramic capacitor of claim 1, wherein the space part provided in the first or second lead part is exposed through at least one surface of the dielectric layer.

9. The multilayer ceramic capacitor of claim 8, wherein the space part provided in the first or second lead part is formed in a position corresponding to a corner portion of the dielectric layer.

10. The multilayer ceramic capacitor of claim 8, wherein the space part provided in the first or second lead part is exposed through one end surface of the dielectric layer.

11. The multilayer ceramic capacitor of claim 8, wherein the space part provided in the first or second lead part is formed in a position corresponding to a corner portion of the dielectric layer so as to be exposed through one end surface of the dielectric layer.

12. The multilayer ceramic capacitor of claim 1, wherein the third lead part has a space part exposed through a lower surface of the dielectric layer.

13. The multilayer ceramic capacitor of claim 5, wherein the fourth lead part has a space part exposed through an upper surface of the dielectric layer.

14. A board for mounting a multilayer ceramic capacitor, comprising:
a printed circuit board having first to third electrode pads disposed thereon; and
the multilayer ceramic capacitor of claim 1 including the first to third external electrodes disposed on the first to third electrode pads, respectively.

15. A board for mounting a multilayer ceramic capacitor, comprising:
a printed circuit board having first to third electrode pads disposed thereon; and
the multilayer ceramic capacitor of claim 2 including the first to third external electrodes disposed on the first to third electrode pads, respectively.

16. A board for mounting a multilayer ceramic capacitor, comprising:
a printed circuit board having first to third electrode pads disposed thereon; and
the multilayer ceramic capacitor of claim 3 including the first to third external electrodes disposed on the first to third electrode pads, respectively.

17. A board for mounting a multilayer ceramic capacitor, comprising:
a printed circuit board having first to third electrode pads disposed thereon; and
the multilayer ceramic capacitor of claim 4 including the first to third external electrodes disposed on the first to third electrode pads, respectively.

18. A board for mounting a multilayer ceramic capacitor, comprising:
a printed circuit board having first to third electrode pads disposed thereon; and
the multilayer ceramic capacitor of claim 5 including the first to third external electrodes disposed on the first to third electrode pads, respectively.

19. A board for mounting a multilayer ceramic capacitor, comprising:
a printed circuit board having first to third electrode pads disposed thereon; and
the multilayer ceramic capacitor of claim 6 including the first to third external electrodes disposed on the first to third electrode pads, respectively.

20. A board for mounting a multilayer ceramic capacitor, comprising:
a printed circuit board having first to third electrode pads disposed thereon; and
the multilayer ceramic capacitor of claim 7 including the first to third external electrodes disposed on the first to third electrode pads, respectively.
